(19) United States
(12) Patent Application Publication
(10) Pub. No.: US 2021/0067062 A1
(43) Pub. Date: Mar. 4, 2021

(54) ELECTRONIC DEVICE AND ELECTRIC ENERGY CONVERSION METHOD THEREOF

(71) Applicant: Coretronic Corporation, Hsin-Chu (TW)

(72) Inventors: Jui-Ta Liu, Hsin-Chu (TW); Chun-Chieh Wang, Hsin-Chu (TW); Chih-Hsiang Li, Hsin-Chu (TW); Kuo-Liang Peng, Hsin-Chu (TW)

(73) Assignee: Coretronic Corporation, Hsin-Chu (TW)

(21) Appl. No.: 17/002,736

(22) Filed: Aug. 25, 2020

(30) Foreign Application Priority Data
Aug. 26, 2019 (CN) 201910788551.1

(51) Int. Cl. H02N 2/18; G03B 21/16; G03B 21/20; G03B 31/00; H02J 7/32; H04R 17/00; H04R 29/00

(52) U.S. Cl. CPC H02N 2/18; G03B 21/16; G03B 21/204; H04R 29/001; H02J 7/32; H04R 17/00; G03B 31/00

(57) ABSTRACT

Provided is an electronic device and an electric energy conversion method. The electronic device includes at least one moving component, a transducer system, a charging and discharging system, and a power supply system. The transducer system has at least one piezoelectric membrane and a storage unit. The at least one piezoelectric membrane is disposed on the at least one moving component, and the storage unit is electrically coupled to the at least one piezoelectric membrane. The charging and discharging system is electrically coupled to the at least one moving component and the transducer system. The power supply system is electrically coupled to the at least one moving component, the transducer system, and the charging and discharging system to provide main energy. The at least one moving component starts to operate, the at least one moving component leads the at least one piezoelectric membrane to deform elastically to generate assisting charges.

### CROSS-REFERENCE TO RELATED APPLICATION

This application claims the priority benefit of China application serial no. 201910788551.1, filed on Aug. 26, 2019. The entirety of the above-mentioned patent application is hereby incorporated by reference herein and made a part of this specification.

### BACKGROUND OF THE DISCLOSURE

### Field of the Disclosure

The present disclosure relates to an electronic device, and more particularly to an electronic device capable of converting mechanical energy into electric energy.

### Description of Related Art

Piezoelectric effect is a phenomenon in which mechanical energy and electric energy are exchanged. There are two kinds of piezoelectric effects. In positive piezoelectric effect, assisting charge is caused by deformation of the piezoelectric material. In short, the positive piezoelectric effect is roughly a process in which mechanical energy is converted into electric energy. In reverse piezoelectric effect, an electric field is applied to the surface of the piezoelectric material, and the piezoelectric material is elongated in the direction of the electric field to generate deformation. In short, the reverse piezoelectric effect is roughly a process in which electric energy is converted into mechanical energy. Currently, there are important applications of piezoelectric materials in speakers, radios, microbalances, and optical devices.

However, the existing piezoelectric materials are rarely used in electronic products such as projectors and computers, or in home appliances such as air conditioners and refrigerators. As a result, existing electronic devices cannot effectively utilize the mechanical energy generated when the products are operated.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention were acknowledged by a person of ordinary skill in the art.

### SUMMARY OF THE DISCLOSURE

The disclosure provides an electronic device and an electric energy conversion method, which can convert mechanical energy generated during operation of a moving component into electric energy through a transducer system to supply a part of electric energy required for operation of the electronic device.

An electronic device of the disclosure includes at least one moving component, a transducer system, a charging and discharging system, and a power supply system. The transducer system has at least one piezoelectric membrane and a storage unit. The at least one piezoelectric membrane is disposed on the at least one moving component, and the storage unit is electrically coupled to the at least one piezoelectric membrane. The charging and discharging system is electrically coupled to the at least one moving component and the transducer system. The power supply system is electrically coupled to the at least one moving component, the transducer system, and the charging and discharging system to provide main electric energy. Specifically, the at least one moving component starts to operate, the at least one moving component leads the at least one piezoelectric membrane to be deformed elastically to generate assisting charge. The assisting charge is adapted to be transmitted to the storage unit for charging and discharging.

The electric energy conversion method of the present disclosure is adapted for an electronic device including at least one moving component, a transducer system, a charging and discharging system, and a power supply system, wherein the transducer system includes at least one piezoelectric membrane and a storage unit, and the piezoelectric membrane is disposed on the at least one moving component. Specifically, the power supply system provides the main electric energy to the at least one moving component, the transducer system, and the charging and discharging system; the at least one moving component starts to operate; the at least one moving component leads the at least one piezoelectric membrane to be deformed elastically and generates assisting charge; and the storage unit receives transmission of the assisting charge for charging and discharging.

Based on the above, the electronic device of the present disclosure disposes the piezoelectric membrane of the transducer system on a moving component capable of generating mechanical energy, and when the moving component starts to operate, the piezoelectric membrane is elastically deformed to generate assisting charge and the assisting charge is transmitted to the storage unit, thereby converting the mechanical energy into electric energy. The assisting charge in the storage unit can be adjusted by the charging and discharging system, and can be stored as backup electric energy, or can be outputted to the moving component or other electronic components in the electronic device to supply a part of the electric energy required for operation, thereby saving power. On the other hand, the transducer system can further detect the storage voltage of the storage unit, and by detecting the voltage change, it can be determined whether the moving component is abnormal.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic block diagram of an electronic device according to an embodiment of the disclosure.

FIG. 1B is a schematic block diagram of an electronic device according to another embodiment of the present disclosure.

FIG. 2 is a schematic block diagram of an electronic device employed as a projector according to another embodiment of the present disclosure.

FIG. 3A to FIG. 3C are schematic plan views showing that the piezoelectric membrane is disposed on a fan, a color wheel, and a speaker, respectively.

FIG. 4 is a flowchart diagram of an electric energy conversion process of the electronic device of FIG. 1A.

### DESCRIPTION OF EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

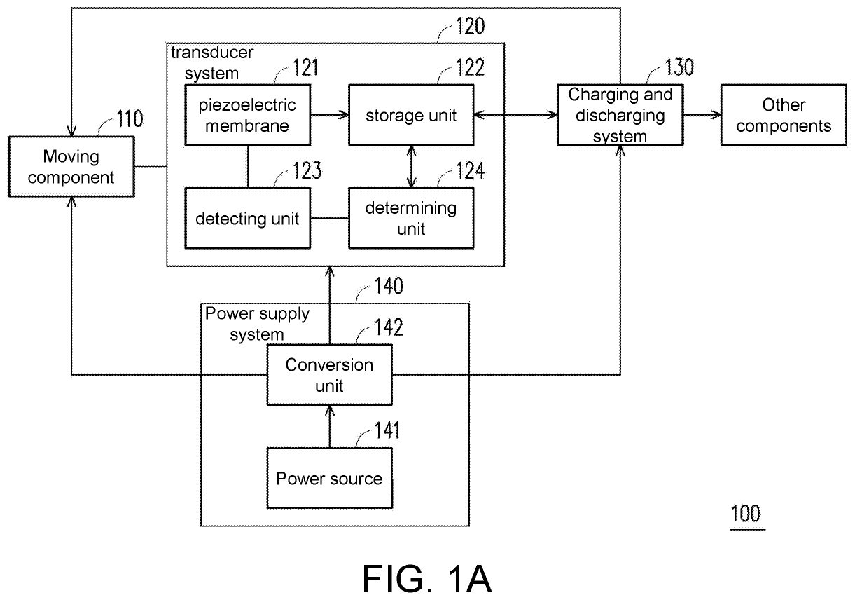

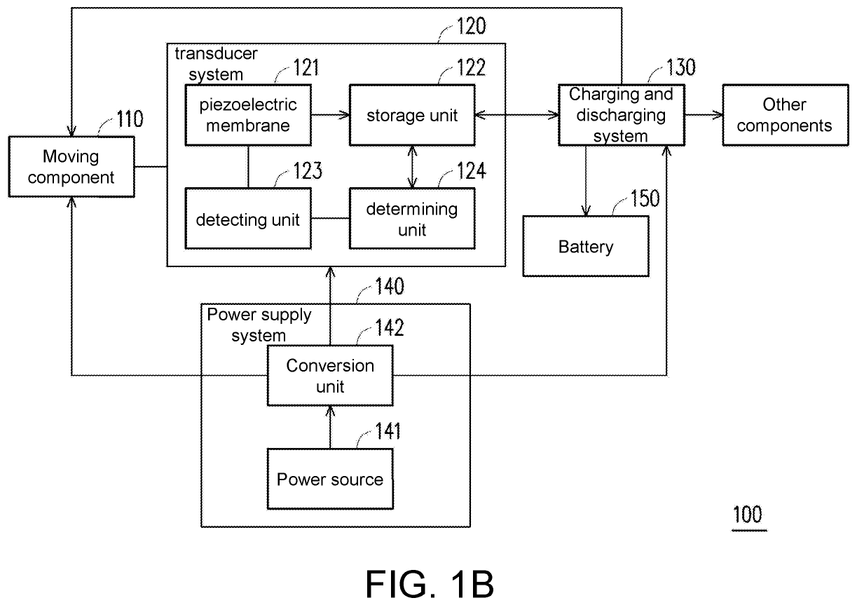

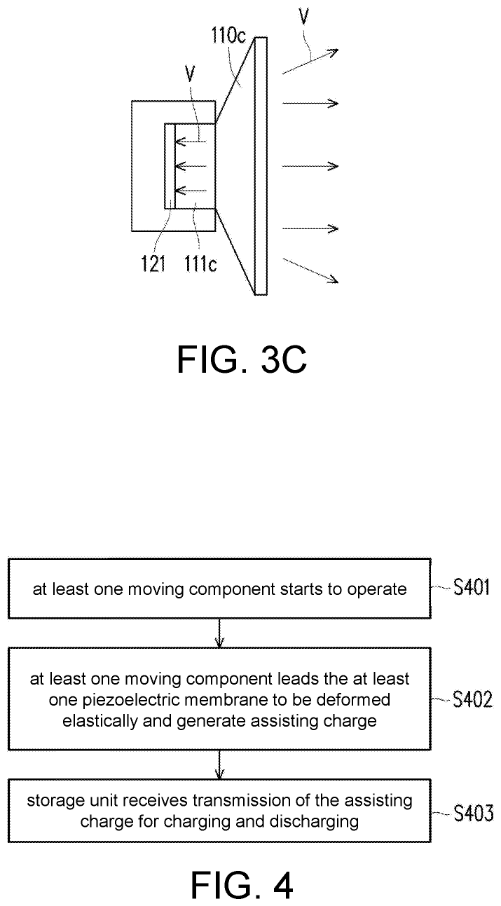

FIG. 1A is a schematic block diagram of an electronic device 100 according to an embodiment of the disclosure. FIG. 4 is a flowchart diagram of an electric energy conversion process of the electronic device of FIG. 1A.

Referring to FIG. 1A, an electronic device 100 of the present disclosure includes at least one moving component 110, a transducer system 120, a charging and discharging system 130, and a power supply system 140. The electronic device 100 is, for example, an electronic product such as a projector or a computer, or a home appliance such as an air conditioner or a refrigerator. The commonality of the above products is that they generate mechanical energy during operation of the at least one moving component 110, such as vibrating, rotating or swing.

The at least one moving component 110 includes, for example, a fan, a color wheel, a speaker, or other components that generate vibration/rotation/swing. The transducer system 120 includes at least one piezoelectric membrane 121 and a storage unit 122. The at least one piezoelectric membrane 121 is disposed on the at least one moving component 110, and the storage unit 122 is electrically coupled to the at least one piezoelectric membrane 121. In detail, please refer to FIG. 1A and FIG. 4, when the electronic device 100 is activated, it operates according to the following process. In step S401, the at least one moving component 110 starts to operate. In step S402, the at least one moving component 110 leads the at least one piezoelectric membrane 121 to be deformed elastically and generate assisting charge. The assisting charge is transmitted to the storage unit 122 for charging and discharging, wherein the storage unit 122 is, for example, a capacitor. In step S403, the storage unit 122 receives transmission of the assisting charge for charging and discharging.

The charging and discharging system 130 is electrically coupled to the at least one moving component 110 and the transducer system 120. The charging and discharging system 130 is configured to manage the power of the storage unit 122, that is, the assisting charge generated by the piezoelectric membrane 121, for example, to transmit the power of the storage unit 122 to the at least one moving component 110 or other components to provide a part of electric energy.

The power supply system 140 is electrically coupled to the at least one moving component 110, the transducer system 120, and the charging and discharging system 130 to provide main electric energy. In detail, the power supply system 140 includes a power source 141 and a conversion unit 142. The power source 141 is, for example, configured for providing high voltage alternating current and transmitting the high voltage alternating current to the conversion unit 142. The conversion unit 142 is, for example, an AC/DC converter, and can be used to convert AC power into DC power and transmit the DC power to the at least one moving component 110, the transducer system 120, and the charging and discharging system 130 to supply the basic electric energy required for operation of the at least one moving component 110, the transducer system 120 and the charging and discharging system 130.

Specifically, when at least one moving component 110 starts to operate and generates mechanical energy, the at least one moving component 110 leads the at least one piezoelectric membrane 121 to be deformed elastically to generate assisting charge, and the assisting charge is adapted to be transmitted to the storage unit 122 for charging and discharging.

Please refer to FIG. 1A. Further, the transducer system 120 includes a detecting unit 123 and a determining unit 124. The detecting unit 123 is electrically coupled to the at least one piezoelectric membrane 121 and the determining unit 124, and the determining unit 124 is electrically coupled to the storage unit 122. Specifically, the detecting unit 123 is configured to detect the operation of the at least one moving component 110, and the determining unit 124 is configured to receive the electric signals of the storage unit 122 and the detecting unit 123 and make a logical determination to return the determining result to the electronic device 100 to execute a corresponding control instruction.

In an embodiment, the detecting unit 123 is configured to measure an output voltage of the at least one piezoelectric membrane 121 during elastic deformation, and the determining unit 124 determines whether the output voltage is zero according to the value returned by the detecting unit 123 to determine whether the at least one moving component 110 is abnormal. When the output voltage is not zero, it means that the at least one piezoelectric membrane 121 continues to be deformed to generate the assisting charge, which indicates that the at least one moving component 110 is still in operation. When the output voltage is zero, it means that the at least one piezoelectric membrane 121 does not generate the assisting charge and has no deformation, which indicates that the at least one moving component 110 is abnormal and does not operate.

In another embodiment, the detecting unit 123 is configured to measure the storage voltage of the storage unit 122, and the determining unit 124 determines whether the storage voltage rises according to the value returned by the detecting unit 123 to determine whether the at least one moving component 110 is abnormal. When the storage voltage rises, it means that the at least one piezoelectric membrane 121 continues to be deformed to input the assisting charge into the storage unit 122, which indicates that the at least one moving component 110 is still in operation. When the storage voltage does not continue to rise, it means that the at least one piezoelectric membrane 121 does not generate the assisting charge, which indicates that the at least one moving component 110 is abnormal and does not operate.

Further, the transducer system 120 determines whether the storage voltage of the storage unit 122 reaches the rated value through the determining unit 124. When the storage voltage of the storage unit 122 is less than the rated value, charging operation is performed, and the assisting charge is accumulated in the storage unit 122. When the storage voltage of the storage unit 122 reaches the rated value, discharging operation is performed, and the assisting charge is transmitted to the charging and discharging system 130, and the charging and discharging system 130 is configured to transmit the assisting charge to the at least one moving component 110 or other components.

FIG. 1B is a schematic block diagram of an electronic device 100 according to another embodiment of the present disclosure. Referring to FIG. 1B, the electronic device 100 further includes a battery 150 electrically coupled to the charging and discharging system 130. When the power supply system 140 is not operating, it provides backup electric energy to the at least one moving component 110, the transducer system 120, and the charging and discharging system 130. Further, the charging and discharging system 130 is configured to transmit the assisting charge generated by the at least one piezoelectric membrane 121 to the battery 150 for energy storage, or to the at least one moving component 110 or other components for partial power supply.

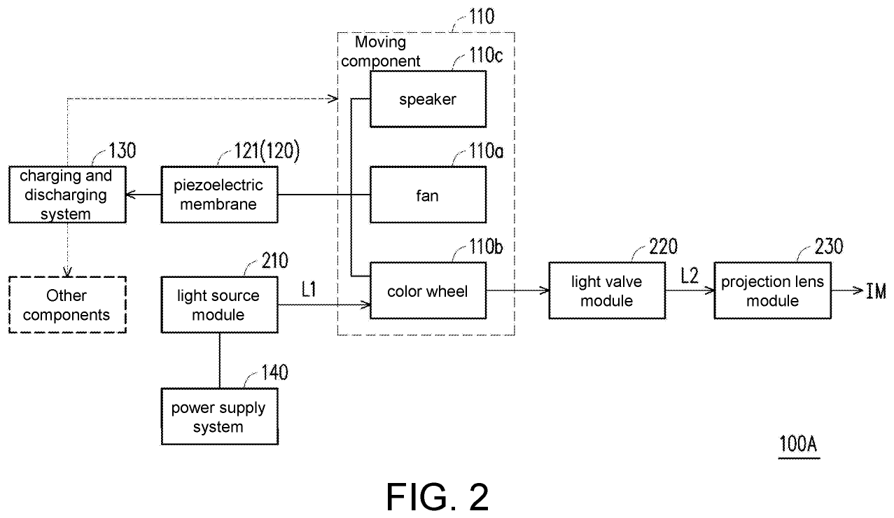

FIG. 2 is a schematic block diagram of an electronic device 100A employed as a projector according to another embodiment of the present disclosure. Referring to FIG. 2, the electronic device 100A of the embodiment is a projector. The projector is a projection device for generating an image frame, and the image frame can be projected onto a screen or a wall to form an image IM, which is mainly applied to a movie screening and conference briefing.

The projector at least includes a light source module 210, a light valve module 220 and a projection lens module 230, wherein the light source module 210 is configured to generate an illumination beam L1, the light valve module 220 is disposed on the transmission path of the illumination beam L1 and is configured to convert the illumination beam L1 into the image beam L2. The projection lens module 230 is disposed on the transmission path of the image beam L2 and is configured to project the image beam L2 as the image IM. The light source module 210 is disposed in the casing of the projector, and the light source module 210 includes, for example, a high-intensity halogen bulb to generate the illumination beam L1. The light source module 210 may include a plurality of visible light emitting components, a plurality of non-visible light emitting components, or a combination of the above. The visible light emitting component may be a light emitting diode (LED) or a laser diode (LD), but is not limited thereto. The visible light emitting component may include a blue light emitting component, and the non-visible light emitting component may include an ultraviolet light emitting diode, but is not limited thereto.

In addition, the projector has a plurality of moving components 110, and the plurality of moving components 110 are a fan 110a, a color wheel 110b and a speaker 110c, respectively. The fan 110a is used to guide external cool air into the projector or to guide the interior hot air to be blown out of the projector to achieve heat dissipation and cooling effect. The color wheel 110b is disposed on the transmission path of the illumination beam L1 for converting the color of the light beam or filtering a part of the color of the light beam through the filter. The speaker 110c is used to play various prompts or sound effects of the projector.

In detail, the illumination beam L1 generated by the light source module 210 can pass through the color wheel 110b, and then convert the illumination beam L1 into the image beam L2 through the light valve module 220 to transmit the converted beam to the projection lens module 230. The projection lens module 230 is disposed on the transmission path of the image beam L2, and the image beam L2 is projected through the projection lens module 230 onto the screen or the wall to form the image IM.

The light valve module 220 may include, but is not limited to, a Digital Micro-mirror Device (DMD), a Liquid Crystal on Silicon (LCOS), or a Liquid Crystal Display Panel (LCD panel). However, in other embodiments, the light valve module 220 can also be a transmissive liquid crystal panel or other spatial light modulator. In this embodiment, the light valve module 220 may have one or more light valves, and the detailed steps and implementation methods corresponding to different numbers of light valves may be sufficiently taught, suggested, and described by common knowledge in the art, so further details are not incorporated herein. The projection lens module 230 is, for example, a combination of one or more optical lenses having a refractive power. The optical lenses, for example, includes a non-planar lens such as a biconcave lens, a lenticular lens, a meniscus lens, a convexo-concave lens, a plano-convex lens, a Plano-concave lens, or the like or various combinations of the above. The present disclosure provides no limitation to the form and type of the projection lens module 230.

Further, the power supply system 140 supplies the main electric energy to activate the projector to start the operation, and the plurality of piezoelectric membranes 121 of the transducer system 120 are respectively disposed on the fan 110a, the color wheel 110b and the speaker 110c. Through the moving of the fan 110a, the color wheel 110b and the speaker 110c, each of the piezoelectric membranes 121 is used to generate a wobble or vibration, thereby generating assisting charge, and the assisting charge is transmitted to the moving components 110 (the fan 110a, the color wheel 110b, and the speaker 110c) or other components after being adjusted by the charging and discharging system 130 to supply a part of the electric energy.

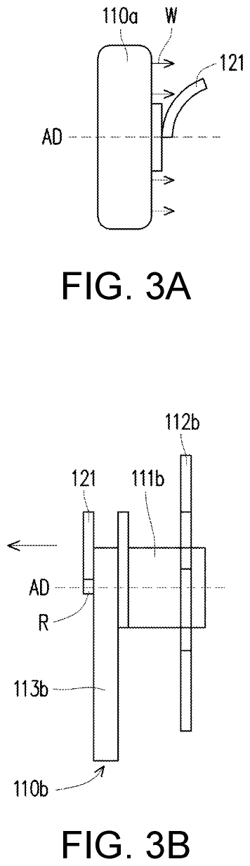

FIG. 3A to FIG. 3C are schematic plan views showing that the piezoelectric membrane 121 is disposed on the fan 110a, the color wheel 110b, and the speaker 110c, respectively. The specific details regarding the configuration of the plurality of piezoelectric membranes 121 of the transducer system 120 disposed on the fan 110a, the color wheel 110b, and the speaker 110c are described below.

Referring to FIG. 2 and FIG. 3A, the at least one moving component 110 includes the fan 110a. One end of the at least one piezoelectric membrane 121 is disposed on the axis of the fan 110a and pivotally rotated along the axial direction AD, such that the at least one piezoelectric membrane 121 is pushed by the air, and the wind W of the fan 110a is also parallel to the axial direction AD and acts on the at least one piezoelectric membrane 121, such that the at least one piezoelectric membrane 121 swings with respect to one side of the fan 110a.

Referring to FIG. 2 and FIG. 3B, the at least one moving component 110 includes the color wheel 110b. One end of the at least one piezoelectric membrane 121 is disposed on the rotating shaft R of the color wheel 110b and pivotally rotated along the axial direction AD, such that the at least one piezoelectric membrane. 121 swings with respect to one side of the color wheel 110b. Specifically, the color wheel 110b includes a variable speed motor 111b, a disk 112b, and a mechanism fixing rod 113b. The rotation speed of the variable speed motor 111b is approximately 300 to 5000 revolutions per minute (rpm). The disk 112b is disposed on the rotating shaft R of the variable speed motor 111b, and the disk 112b is, for example, a combination of filters of a plurality of colors, which can separate the color of the passing illumination beam L1, or the disk 112b is, for example, a light wavelength conversion device that converts the passing illumination beam L1 into a converted beam. The color wheel 110b is fixed on the projector through the mechanism fixing rod 113b. In this way, the disk 112b transmits different monochromatic light at the designated optical path by high-speed rotation to be converted into the image beam L2.

The detecting unit 123 of the transducer system 120 is electrically coupled to the at least one piezoelectric membrane 121 for measuring the output voltage of the at least one piezoelectric membrane 121 when swinging, and converting the output voltage into a corresponding rotating speed, thereby determining, by the determining unit 124, whether the rotation frequency of the fan 110a or the color wheel 110b is abnormal. For example, when the rotation speed of the fan 110a or the color wheel 110b is 500 rpm, the at least one piezoelectric membrane 121 swings and is deformed to generate an output voltage of 0.3V. When the output voltage of 0.3V is maintained constant, it means that the rotation speed 500 rpm of the fan 110a or the color wheel 110b maintains unchanged, and it can be determined that the rotation frequency is normal. When the output voltage changes to be greater than or smaller than 0.3V, it means that the rotation speed of the fan 110a or the color wheel 110b is greater than or smaller than 500 rpm, then it can be determined that the rotation frequency of the fan 110a or the color wheel 110b is abnormal. After the rotation frequency of the fan 110a or the color wheel 110b is determined to be abnormal, the transducer system 120 returns an abnormal signal.

Referring to FIG. 2 and FIG. 3C, the at least one moving component includes the speaker 110c. The at least one piezoelectric membrane 121 is disposed on the yoke 111c of the speaker 110c, for example antimagnetic yoke of the speaker, and receives the sound wave V of the speaker 110c, such that the at least one piezoelectric membrane 121 is vibrated. The detecting unit 123 of the transducer system 120 is electrically coupled to the at least one piezoelectric membrane 121 for measuring the output voltage of the at least one piezoelectric membrane 121 when vibrating. For example, the oscillation frequency of the acoustic wave V is irregular, so when the acoustic wave V is transmitted to the at least one piezoelectric membrane 121, it will cause different degrees of vibration. The at least one piezoelectric membrane 121 generates different magnitude of output voltages according to the corresponding degree of vibration. Therefore, the detecting unit 123 only needs to measure whether the output voltage is generated. When the output voltage is not zero, it is determined that the speaker 110c is normal, and when the output voltage continues to be zero, it is determined that the speaker 110c is abnormal.

In summary, the electronic device of the present disclosure disposes the piezoelectric membrane of the transducer system on a moving component capable of generating mechanical energy, and when the moving component starts to operate, the piezoelectric membrane is elastically deformed to generate assisting charge and the assisting charge is transmitted to the storage unit, thereby converting the mechanical energy into electric energy. Additionally, the assisting charge in the storage unit can be adjusted by the charging and discharging system, and can be stored as backup electric energy, or can be outputted to the moving component or other electronic components in the electronic device to supply a part of the electric energy required for operation.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. An electronic device, comprising: at least one moving component, a transducer system, a charging and discharging system, and a power supply system, wherein:
the transducer system comprising at least one piezoelectric membrane and a storage unit, the piezoelectric membrane being disposed on the at least one moving component, and the storage unit being electrically coupled to the at least one piezoelectric membrane;
the charging and discharging system electrically coupled to the at least one moving component and the transducer system; and
the power supply system electrically coupled to the at least one moving component, the transducer system, and the charging and discharging system to provide main electric energy;
wherein the at least one moving component starts to operate, the at least one moving component leads the at least one piezoelectric membrane to be elastically deformed and generates an assisting charge, the assisting charge is transmitted to the storage unit for charging and discharging.

2. The electronic device of claim 1, wherein the transducer system comprises a detecting unit and a determining unit, the detecting unit is electrically coupled to the at least one piezoelectric membrane and the determining unit, the detecting unit is configured to measure an output voltage of the at least one piezoelectric membrane during elastic deformation, and the determining unit is configured to determine whether the output voltage is zero according to a value returned by the detecting unit to determine whether the at least one moving component is abnormal.

3. The electronic device of claim 2, wherein the at least one moving component comprises a fan or a color wheel, and when the output voltage is maintained constant, the determining unit is configured to determine that the rotation frequency of the at least one moving component is normal, and when the output voltage changes, the determining unit is configured to determine that the rotation frequency of the at least one moving component is abnormal, after the rotation frequency of the fan or the color wheel is determined to be abnormal, the transducer system returns an abnormal signal.

4. The electronic device of claim 1, wherein the transducer system comprises a detecting unit and a determining unit, the detecting unit is electrically coupled to the at least one piezoelectric membrane and the determining unit, the detecting unit is configured to measure a storage voltage of the storage unit, and the determining unit is configured to determine whether the storage voltage rises to determine whether the at least one moving component is abnormal.

5. The electronic device of claim 1, wherein the transducer system comprises a detecting unit and a determining unit, the detecting unit is electrically coupled to the at least one piezoelectric membrane and the determining unit, and the determining unit is configured to determine whether the storage voltage of the storage unit reaches a rated value, wherein when the storage voltage of the storage unit is smaller than the rated value, charging operation is performed, and the assisting charge is accumulated in the storage unit; or when the storage voltage of the storage unit reaches the rated value, discharging operation is performed, and the assisting charge is transmitted to the charging and discharging system, and the charging and discharging system is configured to transmit the assisting charge to the at least one moving component.

6. The electronic device of claim 1, wherein the at least one moving component comprises a fan, and one end of the at least one piezoelectric membrane is disposed on an axis of the fan and pivotally rotated in an axial direction, such that the at least one piezoelectric membrane swings.

7. The electronic device of claim 1, wherein the at least one moving component comprises a color wheel, and one end of the at least one piezoelectric membrane is disposed on a rotating shaft of the color wheel and pivotally rotated along an axial direction, such that the at least one piezoelectric membrane swings.

8. The electronic device of claim 1, wherein the at least one moving component comprises a speaker, and the at least one piezoelectric membrane is disposed on a yoke of the speaker and receives acoustic waves of the speaker such that the at least one piezoelectric membrane vibrates.

9. The electronic device of claim 1, wherein the power supply system comprises a power source and a conversion unit, the power source is configured to provide an alternating current and transmit the alternating current to the conversion unit, and the conversion unit converts the alternating current into a direct current and supplies the direct current to the at least one moving component, the transducer system, and the charging and discharging system.

10. An electric energy conversion method adapted for an electronic device, the electronic device comprising at least one moving component, a transducer system, a charging and discharging system, and a power supply system, wherein the transducer system comprises at least one piezoelectric membrane and a storage unit, the piezoelectric membrane is disposed on the at least one moving component, and the electric energy conversion method comprises:
providing, by the power supply system, main electric energy to the at least one moving component, the transducer system, and the charging and discharging system;
starting, operation of the at least one moving component;
leading, by the at least one moving component, the at least one piezoelectric membrane to be elastically deformed and generate an assisting charge; and
receiving, by the storage unit, the assisting charge and transmit the assisting charge for charging and discharging.

11. The electric energy conversion method of claim 10, wherein the transducer system performs: measuring an output voltage of the at least one piezoelectric membrane during elastic deformation, and determining whether the output voltage is zero according to a value returned by a detecting unit of the transducer system, thereby determining whether the at least one moving component is abnormal.

12. The electric energy conversion method of claim 11, wherein the at least one moving component comprises a fan or a color wheel, when the output voltage is maintained constant, determining that the rotation frequency of the at least one moving component is normal, and when the output voltage changes, determining that the rotation frequency of the fan or the color wheel is abnormal, and after the rotation frequency of the fan or the color wheel is determined to be abnormal, the transducer system returns an abnormal signal.

13. The electric energy conversion method of claim 10, wherein measuring, by the transducer system, a storage voltage of the storage unit, and determines, by a determining unit, whether the storage voltage of the storage unit reaches a rated value.

14. The electric energy conversion method of claim 13, wherein when the storage voltage of the storage unit is smaller than the rated value, charging operation is performed, and the assisting charge is accumulated in the storage unit; or when the storage voltage of the storage unit reaches the rated value, performing discharging operation, and transmitting the assisting charge to the charging and discharging system, and transmitting, by the charging and discharging system, the assisting charge to the at least one moving component.
